(19) United States
(12) Patent Application Publication
(10) Pub. No.: US 2002/0109511 A1
(43) Pub. Date: Aug. 15, 2002

(54) Method of determining a fuel concentration in the electrolyte of fuel cells operated with liquid fuel

(76) Inventor: Michael Frank, Uttenreuth (DE)

Correspondence Address: LERNER & GREENBERG, P.A., Post Office Box 2480, Hollywood, FL, 33022-2480, US

(21) Appl. No.: 10/078,123

(22) Filed: Feb. 19, 2002

Related U.S. Application Data
(63) Continuation of application No. PCT/DE00/02771, filed on Aug. 16, 2000.

(30) Foreign Application Priority Data
Aug. 16, 1999 (DE) 199 38 790.7

(51) Int. Cl. G01R 27/26

(52) U.S. Cl. 324/663

(57) ABSTRACT

The fuel concentration in the electrolyte of fuel cells that are operated with liquid fuel is determined. Specifically, the concentration of methanol in the electrolyte of direct methanol fuel cells can be measured. The capacitance of a capacitor is measured with the fuel/electrolyte mixture placed as a dielectric. The dielectric constant of the mixture is proportional to the measured capacitance and, upon determining the dielectric constant of the mixture, the fuel concentration in the mixture or in the electrolyte can be calculated.

### CROSS-REFERENCE TO RELATED APPLICATION

This is a continuation of copending International Application No. PCT/DE00/02771, filed Aug. 16, 2000, which designated the United States.

### BACKGROUND OF THE INVENTION

1. Field of the Invention

The invention relates to a method for determining the fuel concentration in the electrolyte of fuel cells, which are operated with liquid fuel. In the invention, the fuel is preferably, although not exclusively, methanol, so that the invention is particularly suitable for determining the concentration of methanol in the electrolyte of direct methanol fuel cells (DMFCs). In addition, the invention relates to a device for carrying out the method.

To maintain the optimum operating parameters in fuel cells that are operated with liquid fuels, it is necessary to control the fuel concentration. For this purpose, the current concentration has to be determined.

European published patent application EP 0 684 469 A2 describes a measuring assembly for determining the concentration of low molecular weight alcohols in water or acids. That measurement device has a porous anode for the electrochemical oxidation of alcohol, a cathode for the electrochemical reduction of oxygen, an ion-conducting membrane arranged between the anode and the cathode, and a diffusion-limiting membrane, which is arranged on that side of the anode that is remote from the ion-conducting membrane.

In direct methanol fuel cells (DMFCs), the fuel methanol is directly oxidized electrochemically, i.e. is reacted without the intermediate reforming step (cf. in this connection, for example, M. Waidhas in K. Ledjeff (Ed.) “Brennstoffzellen: Entwicklung, Technologie, Anwendung” [Fuel cells: development, technology, application], C. F. Müller Verlag GmbH, Heidelberg 1995, pages 137-56). To achieve the optimum operating point in a DMFC, it is necessary to operate with excess dilute fuel. Since excess fuel is used, it is imperative—in order to avoid relatively large amounts of waste—to circulate the fuel and to establish the correct concentration by metering in concentrated fuel. For this purpose, it is necessary for the currently prevailing fuel concentration to be measured.

### SUMMARY OF THE INVENTION

It is accordingly an object of the invention to provide a method of determining the fuel concentration in the electrolyte of a fuel cell operated with liquid fuel, which overcomes the above-mentioned disadvantages of the heretofore-known devices and methods of this general type and which provides for a simple on-line measuring method for determining the fuel concentration in the fuel cell electrolyte, specifically with the possibility of setting up a closed control circuit.

With the foregoing and other objects in view there is provided, in accordance with the invention, a method of determining a fuel concentration in an electrolyte of a fuel cell operated with liquid fuel, which comprises: conducting a fuel/electrolyte mixture through a capacitor as a dielectric, measuring a capacitance of the capacitor, determining a dielectric constant of the fuel/electrolyte mixture from the capacitance, and calculating therefrom the fuel concentration in the fuel cell electrolyte.

In a preferred embodiment of the invention, the capacitance is repeatedly measured at a frequency of >20 kHz.

The novel process is particularly suitable for implementation in direct methanol fuel cells (DMFCs). In that case, the method determines a methanol concentration in the electrolyte of the direct methanol fuel cells, and a methanol/water mixture is used as the fuel/electrolyte mixture.

With the above and other objects in view there is also provided, in accordance with the invention, a device for determining a fuel concentration of an electrolyte of a fuel cell operated with liquid fuel. The novel system includes a capacitor disposed to be exposed to a fuel/electrolyte mixture of the fuel cell, and a measurement device connected to the capacitor for measuring a capacitance of the capacitor, for determining a dielectric constant of the fuel/electrolyte mixture, and for calculating the fuel concentration in the fuel/electrolyte mixture.

Preferably, the capacitor is a plate capacitor. Advantageously, the capacitor plates are formed with a thin insulating layer, such as barium strontium titanate.

According to the invention, the object is achieved by the measures of the patent claim. An associated device forms the subject matter of patent claim 4. Refinements of the method and of the device, in particular for use in direct methanol fuel cells, are given in the subclaims.

In the invention, with the fuel/electrolyte mixture as dielectric, the capacitance of a capacitor is measured, and this measurement is used to determine the dielectric constant of the mixture and then to work out the fuel concentration. This method makes use of the fact that the fuel mixture comprises only the constituents fuel and electrolyte. The dielectric constant of this mixture is dependent on the concentration of the fuel. Since the dielectric constant of the mixture varies in direct proportion to the mixing ratio of the constituents, it is possible to work out the methanol concentration by measuring the dielectric constant.

The device for carrying out the method according to the invention is used to measure the capacitance C of a capacitor with the fuel mixture as dielectric. In this measurement, C=∈ᵣ·C₀, where C₀ is the capacitance of the capacitor without dielectric. Therefore, the basis of the invention is that, given a known fuel composition and the fact that the measured variable varies in direct proportion to the concentration, it is possible to determine the concentration without using a measured variable which is specific to the fuel.

The method according to the invention has in particular the following advantages:

The determination of the concentration is simple and inexpensive to carry out.

The measurement is stable over a prolonged period and requires no maintenance outlay.

It is easy to compensate for the effects of temperature on the measuring method, and consequently the method can be used over a wide temperature range, as is present, for example, when used in mobile applications.

Further details and advantages of the invention will emerge from the description of exemplary embodiments, which proceed from a measuring cell for determining the capacitance of a liquid that serves as dielectric. The measuring cell forms a sensor for measuring the concentration of constituents which vary in the liquid.

The capacitance is measured, i.e. the primary measured variable is determined, by applying an alternating voltage to the measuring cell and analyzing the resulting alternating current through the cell. To prevent the measurements from being distorted by double-layer capacitance fractions, it is advantageous for the measurement frequency to be selected to be sufficiently high. The measurement frequency is preferably >20 kHz. The liquid fuel may in particular be an alcohol, such as methanol, ethanol, propanol and glycol, or hydrazine. The electrolyte may be water, an acid, such as sulfuric acid, or a base, such as aqueous potassium hydroxide solution. It is preferable for the fuel/electrolyte mixture to be a methanol/water mixture.

Although the fuel mixture serves as the dielectric, it does have a certain electrical conductivity. This conductivity originates both from the intrinsic conductivity of the water and from the methanol which is present in the mixture, as well as any carbon dioxide which may be present, formed through the oxidation of the methanol. Consequently, it may be expedient to take account of the effect of the loss resistance of the measurement capacitor. For this purpose, the measured alternating current can be analyzed in terms of magnitude and phase, and the capacitive fraction can be evaluated.

The measurement cell therefore forms a sensor for determining the fuel concentration and has a capacitor through which the fuel/electrolyte mixture can flow and means for measuring the capacitance, for determining the dielectric constant and for working out the fuel concentration. The fuel mixture is passed through the capacitor whose capacitance is being measured. Given a predetermined geometry, the capacitance is a direct measure of the dielectric constant and therefore of the concentration of the fuel.

In a preferred embodiment, the capacitor is a plate-type capacitor. A capacitor of this type may, for example, have a plate surface area of 2 cm² and a plate spacing of 1 mm. By way of example, at a concentration of 2 mol/l, the capacitance is approximately 170 pF. In addition to a planar gap geometry, however, a comb-like or cylindrical geometry is also suitable. Appropriate devices may be utilized to ensure that it is impossible for any gas bubbles to collect in the measurement gap.

The materials which are used in the sensor for the housing or the capacitor electrodes must be compatible with the fuel mixture and must be sufficiently stable within the entire temperature range that is of relevance to the particular application. Particularly in the case of methanol/water mixtures, polyethylene, polytetrafluoroethylene or glass are examples of suitable materials for the insulating parts of the measuring cell. The capacitor plates may, for example, be made from stainless steel.

In order to construct a closed-loop fuel control circuit, the sensor according to the invention may be arranged ahead of the fuel cell in the flow feed direction. In this case, a mixing section lies ahead of the sensor into which, firstly, the depleted fuel mixture from the fuel cell and, secondly, “concentrated fuel”, i.e. pure fuel or a concentrated fuel/electrolyte mixture, are introduced. The sensor supplies a signal that is a measure of the actual concentration of the fuel at the entry to the fuel cell. This signal is then compared with a desired value, and then more or less concentrated fuel is fed to the mixing section, so that a fuel mixture of the desired concentration is present at the entry into the fuel cell.

In an alternative construction, the sensor is arranged upstream of the mixing section and supplies a signal for the actual concentration of the fuel upstream of the mixing section. In combination with a signal for the mass or volumetric flow rate of the fuel mixture, it is then possible to determine the amount of fuel required in order to obtain the desired concentration and to meter in that amount of fuel.

With regard to the control process, the following is of importance. The sensor is used to measure the concentration of the fuel and, by control operations, to set it to a specific concentration. However, the amount of fuel to be metered to the fuel mixture is dependent—in addition to the actual concentration—on the fuel mixture flow rate which, however, is variable and load-dependent. Consequently, the time and control constants in the control circuit are also load-dependent.

For control purposes, it is necessary not only to record the actual value but also to specify a desired value. Fundamentally different procedures are possible in this respect. For example, the measuring cell can be calibrated and in this way—by means of the relationship between capacitance and concentration—the actual value can be determined as an absolute variable and can be compared to the desired value which is predetermined as a number in a control computer. Alternatively, the desired value can be produced by means of a second sensor, which is filled with a reference solution. It is then unnecessary for the sensors to be calibrated absolutely, but rather it is merely necessary to ensure that the two sensors have the same characteristic curve. The comparison between actual value and desired value can then be effected, for example, by means of a bridge circuit.

The voltage source has to be able to drive not only the capacitive fraction but also the ohmic fraction of the sensor impedance. It may therefore be advantageous to provide the capacitor plates with a thin insulating layer of a high dielectric constant, for example of barium strontium titanate. This makes it possible to avoid problems which arise from the conductivity of the fuel mixture.

In methanol/water mixtures for the operation of direct methanol fuel cells, the required methanol concentration is generally less than 10% by weight; specifically, 0.5 to 2.5 molar solutions are used, the concentration being in particular 2 mol/l. In this range, the variation in the dielectric constant is approximately 6%. To be able to determine the fuel concentration with an accuracy of approximately 10%, it is therefore necessary for the absolute determination of the capacitance to be accurate to better than 0.6%. Therefore, it is advantageous to additionally provide a reference capacitor with a dielectric within the desired concentration range for the fuel.

I claim:

1. A method of determining a fuel concentration in an electrolyte of a fuel cell operated with liquid fuel, which comprises: conducting a fuel/electrolyte mixture through a capacitor as a dielectric, measuring a capacitance of the capacitor, determining a dielectric constant of the fuel/electrolyte mixture from the capacitance, and calculating therefrom the fuel concentration in the fuel cell electrolyte.

2. The method according to claim 1, which comprises repeatedly measuring the capacitance at a frequency of >20 kHz.

3. The method according to claim 1, which comprises providing a direct methanol fuel cell and determining a methanol concentration in the electrolyte of the direct methanol fuel cells, wherein a methanol/water mixture is used as the fuel/electrolyte mixture.

4. In combination with a fuel cell operated with liquid fuel, a device for determining a fuel concentration of an electrolyte of the fuel cell, comprising: a capacitor disposed to be exposed to a fuel/electrolyte mixture of the fuel cell, and a measurement device connected to said capacitor for measuring a capacitance of said capacitor, for determining a dielectric constant of the fuel/electrolyte mixture, and for calculating the fuel concentration in the fuel/electrolyte mixture.

5. The device according to claim 4, wherein said capacitor is a plate capacitor.

6. The device according to claim 5, wherein said capacitor has capacitor plates formed with a thin insulating layer.

7. The device according to claim 5, wherein said capacitor has capacitor plates formed with a thin insulating layer of barium strontium titanate.

8. The device according to claim 4, which further comprises a reference capacitor with a dielectric within the desired concentration range of the fuel.

9. The device according to claim 4 incorporated in a fuel control circuit of a direct methanol fuel cell.

10. The device according to claim 8 incorporated in a fuel control circuit of a direct methanol fuel cell, and wherein said reference capacitor is used to define a desired value in the control circuit.

11. The device according to claim 9, wherein the control circuit has load-dependent time and control constants.
